(19) United States
(12) Patent Application Publication
(10) Pub. No.: US 2005/0266592 A1
(43) Pub. Date: Dec. 1, 2005

(54) Method of fabricating an encapsulated chip and chip produced thereby

(75) Inventor: Brad L. Hawthorne, Saratoga, CA (US)

Correspondence Address: WALLACE G. WALTER, 5726 CLARENCE AVE, ALEXANDRIA, VA, 22311-1008, US

(73) Assignee: Intersil Americas, Inc.

(21) Appl. No.: 11/034,869

(22) Filed: Jan. 14, 2005

Related U.S. Application Data
(60) Provisional application No. 60/575,101, filed on May 28, 2004.
(60) Provisional application No. 60/575,096, filed on May 28, 2004.

(51) Int. Cl. H01L 21/00

(52) U.S. Cl. 438/27

(57) ABSTRACT

A method of fabricating an integrated circuit having a window therein for transmitting optical energy to and/or from an optically active area of the underlying die includes depositing a quantity of an uncured optically transmissive material on the die portion of a integrated circuit preform, placing the window on the surface of the uncured optically transmissive material, placing the so-assembled components into a curing mold having surfaces thereof that establish the dimensional relationship and/or alignment between the window and the optically active area or areas of the underlying die, and curing the optically transmissive material to establish the dimensional relationship and/or alignment between the window and the optically active area or areas of the underlying die, and, thereafter, applying a conventional encapsulating material thereto to form the final package.

### CROSS-REFERENCE TO RELATED APPLICATION

This application claims the benefit of commonly owned U.S. Provisional Patent Application 60/575,101 filed by the inventor herein on May 28, 2004. This application is related to commonly owned U.S. Provisional Patent Application 60/575,096 filed May 28, 2004 by the inventor herein and U.S. patent application (Docket SE-2071) filed on even date herewith by the inventor herein, both entitled “Encapsulated Chip And Method Of Fabrication Thereof.”

### BACKGROUND OF THE INVENTION

The present invention relates to the fabrication of encapsulated integrated circuits and, more particularly, to a method for the fabrication of an encapsulated integrated circuit having optically active areas or devices thereon and the encapsulated integrated circuits resulting therefrom.

Integrated circuit devices that include an optically active area or areas typically incorporate a window of glass, quartz, plastic, or similar material(s) that allows the transmission of optical energy therethrough to and/or from the optically active area or areas of the chip structure. Typically, the window is located on the top surface of the encapsulated chip and allows optical energy to pass to and/or from the optically active areas of the underlying die. In general, it is desirable to reduce the fabrication costs of such integrated circuits, since the placement and alignment of the window oftentimes requires the use of specially designed posts, columns, or similar structures to hold the window in place relative to the underlying die during the encapsulation process.

### SUMMARY OF THE INVENTION

A method of fabricating an integrated circuit having a window therein for transmitting optical energy to and/or from an optically active area of the underlying die includes depositing a quantity of an uncured optically transmissive material on the die portion of an integrated circuit preform, placing the window on the surface of the uncured optically transmissive material, placing the so-assembled components into a curing structure or mold having surfaces thereof that establish the dimensional relationship and/or alignment between the window and the optically active area or areas of the underlying die, and curing the optically transmissive material to establish the dimensional relationship and/or alignment between the window and the optically active area or areas of the underlying die, and, thereafter, applying a conventional encapsulating material thereto to form the final package.

The method of the present invention uses the surfaces of the curing structure or mold to establish the dimensional relationship and/or alignment between the window and the underlying chip while the optically transmissive material is in its uncured or partially cured state to thereby reduce in-process assembly costs of the resulting package.

The full scope of applicability of the present invention will become apparent from the detailed description to follow, taken in conjunction with the accompanying drawings, in which like parts are designated by like reference characters.

### BRIEF DESCRIPTION OF THE DRAWING

FIG. 1 is a side elevational view, in cross-section, of an exemplary integrated circuit chip structure in accordance with the preferred embodiment;

FIG. 2 is a side elevational view of a die or chip mounted on an underlying lead frame;

FIG. 3 is a side elevational view of the die of FIG. 2 in which bonding wires electrically connect conductive pads on the die to selected leads on the lead frame;

FIG. 4 is a side elevational view of the assembly of FIG. 3 with a deposit of uncured optical coupling media deposited on the face of the die;

FIG. 5 is a side elevational view of the assembly of FIG. 4 with a window placed atop the deposit of uncured optical coupling media;

FIG. 6 is a side elevational view of the assembly of FIG. 5 with the window depressed or pressed a selected distance into the deposit of uncured optical coupling media when placed in a curing mold;

FIG. 7 is an enlarged detail showing the manner by which the window of FIG. 6 is depressed or pressed a selected distance into the deposit of uncured optical coupling media;

FIG. 8 is an illustration of the structure of FIG. 6 and the final encapsulation thereof; and

FIG. 9 illustrates the optional use of an anti-flash tape placed on the window to limit or prevent encapsulation material from covering the window surface.

### DESCRIPTION OF THE PREFERRED EMBODIMENT

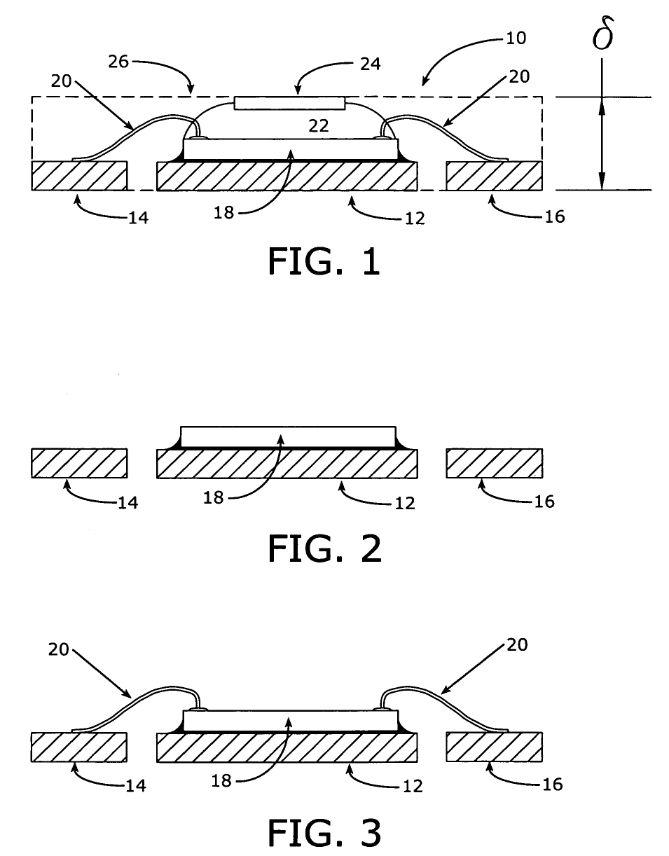

An encapsulated semiconductor device of the type fabricated in accordance with the present invention is shown in exemplary cross-section in FIG. 1 and is designated therein by the reference character 10. As shown, the semiconductor device 10 includes a die pad 12 that can be part of a larger lead frame of which leads 14 and 16 are representative. An integrated circuit die 18 is affixed to one surface of the die pad 12 by a conventional die attach adhesive or cement (unnumbered). Conductive pads or lands (not shown) on the die 18 are electrically connected to the various leads by conductors 20 (typically gold or aluminum or alloys thereof) that are secured in place on their respective pads or lands by suitable bonding techniques including, for example, thermocompression or thermosonic techniques or variants thereof. A optical coupling media 22 is located over and occupies a selected volume on the top surface of the die 18 and is designed, as explained more fully below, to transmit optical energy to and/or from optical devices on the die 18. A window 24 is located on or within the optical coupling media 22 and acts as the interface between the interior components of the semiconductor device 10 and the exterior thereof. Lastly, an encapsulating material 26, such as a conventional opaque resin or epoxy material, surrounds the interior components to define the outline of the semiconductor “package.”

As represented by the dimension δ, the semiconductor device 10 has an overall height or top-to-bottom dimension.

The semiconductor device 10 of FIG. 1 is prepared in accordance with the sequence of FIGS. 2-8. The embodiment of FIGS. 2-8 is described in the context of a QFN “no-lead” type package; as can be appreciated, the invention is not so limited and can be used in the context of other types of semiconductor packages, including, for example, ball-grid arrays, pin arrays, and classic dual-in-line packages.

As shown in FIG. 2, the circuit die 18 is attached to the die pad 12 using a conventional die attach adhesive or cement. In automated systems, the die 18 can be attached using conventional pick-and-place robotic machinery. The die 18 includes one or more optical devices or circuits formed therein or thereon. The optical devices can include devices for responding to incident optical radiation or for generating and emitting optical radiation including, for example, photoreceptive diodes/transistors or other optically active devices and photodiodes or lasers. As used herein, optical devices are those that either respond to and/or emit radiation from and between the infrared region through the visible region and into and to the ultraviolet region of the electromagnetic spectrum.

As represented in FIG. 3 and after the placement of the die 18 on its die pad 12, the die 18 is electrically connected to its lead frame using conventional bonding wires 20. More specifically, individual conductive pads on the die 18 are connected to respective leads (as represented by the leads 14 and 16) by wires 20 using conventional ball bond (i.e., “nail-head”) or wedge bond formations and thermocompressive or thermosonic bonding techniques.

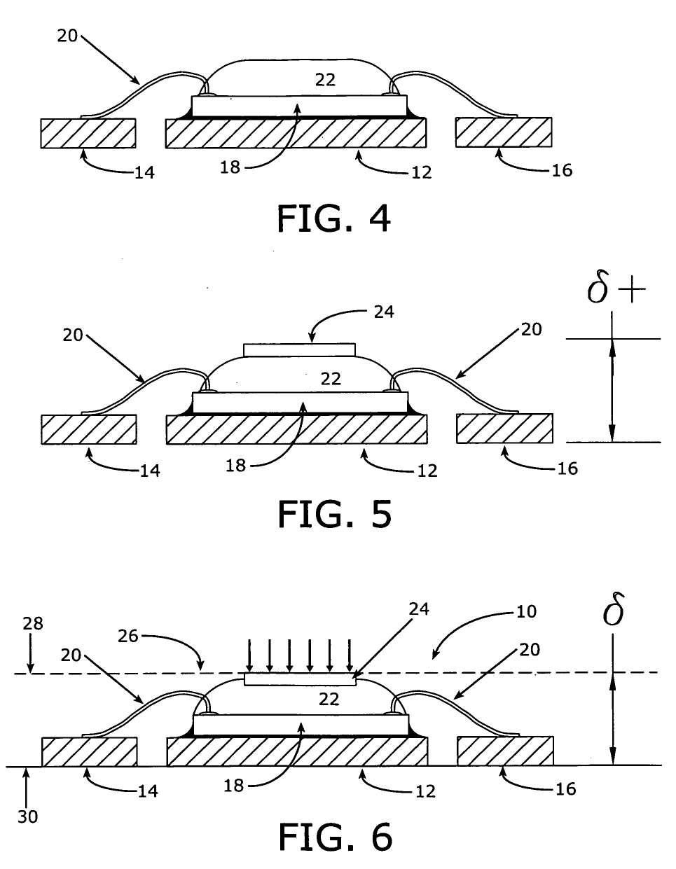

After the wire bonding step is completed and as shown in FIG. 4, a selected volume of an optical coupling media 22 is deposited on the exposed surfaces of the die 18. The optical coupling media 22 is typically an uncured or partially cured optical material such as an epoxy, acrylate, resin, or silicone that, in its cured state, is sufficiently transparent to transmit or convey optical energy to and/or from the optical devices or circuits formed on or in the die 18. In a preferred application of the present invention, HIPEC® Q1-4939 solventless silicone gel from the Dow Corning Corp., Midland, Mich. 48686 is used. This material, in its initial uncured state, is applied as a soft, pliable gel to the surface of the die 18 and cures to a resilient elastomeric material. If desired, other materials, including conventional hardenable epoxies and resins can be used, provided they possess adequate optical properties.

Once the optical coupling media 22 is deposited on the die 18 and as shown in FIG. 5, the window 24 is placed on the deposited material. The window 24 can take the form of a glass, quartz, silica, or plastic, or similar material appropriately sized for the die 18 and the application; thus, the window 24 can be sized to be substantially co-extensive with surface area of the die 18, smaller than the area of the die 18, or larger than the area of the die 18. In the preferred embodiment, the window 24 is formed from conventional amorphous glass that is saw-cut from larger sheets into the desired size. If desired, the particular material from which the window is formed can have uniform or non-uniform transmission characteristics for the wavelength or wavelengths to be transmitted to and/or from the die 18, and, further, can be provided with one or more coatings to enhance or otherwise control its optical properties and/or provide physical abrasion resistance to the exposed surface of the window 24. In automated assembly systems, the window 24 can be positioned and placed upon the optical coupling media 22 by a conventional pick-and-place robotic system.

In FIG. 5, the window 24 is shown a being placed atop the uncured or partially cured optical coupling media 22; if desired, the window 24 can be pressed into or depressed into the optical coupling media 22 as part of the window placement operation. As shown by the dimension Δ+ on the right of FIG. 5, the overall height or top-to-bottom dimension of the assembly of FIG. 5 after placement of the window 24 is the final height δ of the finished package plus an additional increment beyond the final height value. As will become evident below, the quantitative value of the additional increment is typically less than the thickness dimension of the window 24. In general, the uncured optical coupling media 22 is sufficiently viscous to be both shape-sustaining and sufficiently stiff to hold the window 24 in its as-placed position during subsequent handling and molding operations.

After the window 24 is placed upon the uncured or partially cured optical coupling media 22, the assemblage of FIG. 5 is placed in a conventional encapsulation mold or equivalent curing jig/fixture. The mold or equivalent curing jig/fixture includes surfaces that define the final dimensions of the finished semiconductor package. As shown in FIG. 6, the surfaces 28 and 30 represent the major mold surfaces on the upper and bottom sides of the to-be-encapsulated assembly. The dimension or spacing between these two mold surfaces is less than the δ+ dimension mentioned in the context of FIG. 5. The mold surface 28, as the mold is closed, contacts the upper surface of the window 24 and presses the window 24 in the direction of the arrows in FIG. 6 into the optical coupling media 22. The mold surface 30 functions to define a reference plane or “baseline” or “base plane” that, in conjunction with the mold surface 28, dimensionally defines the position the window 24 relative to the die 18 and positionally maintains the window 24 in place during subsequent curing and encapsulation processes.

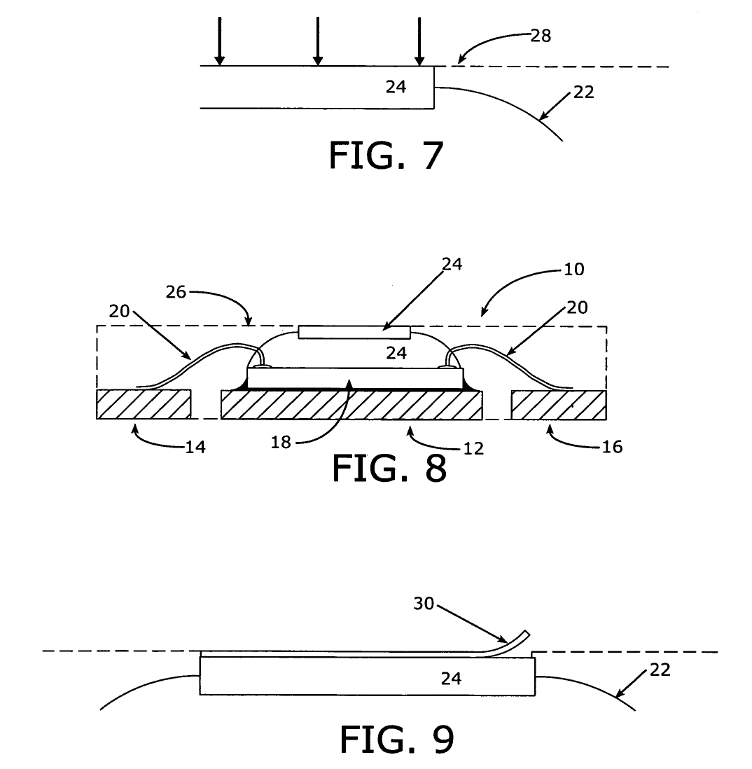

As the mold surface 28 presses the window 24 into the optical coupling media 22, the media will tend to displace somewhat peripherally about the various sides or edges of the window 24; in general, this peripheral spreading or “bleeding” results in an acceptable lateral or peripheral expansion of the optical coupling media 22. As shown, in FIG. 7, one consequence of pressing the window 24 into the optical coupling media 22 is that the peripheral sides of the window 24 will come into contact with the optical coupling media 22. In general, it is preferred that some contact on the peripheral sides takes place to “sink” or embed the window 24 in the optical coupling media 22. As will be apparent, it is also preferable that some portion of the peripheral sides of the window 24 remain exposed after the window 24 is pressed into place.

Once the window 24 is positioned as described above in relationship to FIG. 8, the optical coupling media 22 is subject to a full or partial curing step by application of heat at a temperature and duration appropriate for the optical curing media used. For individual piece-parts and small batch quantities, curing can be accomplished in conventional “box” ovens and for large quantities, production ovens/molds can be used. In the case of the HIPEC® media mentioned above, exposure to 150° C. for about two hours is sufficient to effect a cure. Where a UV-curable material is used, full or partial curing can be accomplished by exposure to UV radiation in accordance with the supplier requirements.

After the optical coupling media 22 is partially cured or fully cured and as shown in FIG. 8, the assembly is retained in place in the mold and subject to a conventional encapsulation step by which a typically opaque, filled uncured resin is injected into and fills the mold cavity and is thereafter cured to form the final “package.”

It is not necessary for the curing of the optical coupling media 22 to be completed prior to the conventional encapsulation procedure. For example, the optical coupling media 22 can be subject to curing for a sufficient period of time such that the now-partially cured optical coupling media 22 will remain dimensionally stable during the subsequent encapsulation step so that the curing of the encapsulation material will concurrently “finish” the curing of the optical coupling media 22.

If desired and as shown in FIG. 9, a removable adhesive-backed “anti-flash” tape 30 can be provided on the exterior surface of the window 24. This tape 30, which is shown partially “peeled” from the window 24 in FIG. 9, functions to protect the surface of the window 24 during processing and functions to temporarily seal the peripheral margins of the window 24 during the encapsulation step of FIG. 8 to minimize or prevent any encapsulating material from infiltrating onto the exterior surface of the window 24. Once the encapsulating step is completed, the tape 30 can be removed.

In the process described above, the optical coupling media 22 is deposited on the die 18 and the window 24 then placed in position; as can be appreciated, the optical coupling media can be deposited or placed on the underside of the window 24 and the window 24 with its deposit of optical coupling media 22 can then be placed in position on the die.

The present invention thus provides a method for forming a semiconductor device package of the type having an optical window therein and the product formed thereby.

As will be apparent to those skilled in the art, various changes and modifications may be made to the illustrated embodiment of the present invention without departing from the spirit and scope of the invention as determined in the appended claims and their legal equivalent.

1. A method of fabricating a semiconductor package having a die mounted on a die pad, the die having at least one optical component therein or thereon, comprising:
depositing a selected quantity of an uncured optically transmissive material on at least that portion or those portions of the die having the at least one optical component therein or thereon;
placing an optically transmissive window on the deposit of optically transmissive material;
pressing the window into the deposit of optically transmissive material until a selected dimension between the window and a selected reference plane is attained; and
curing the optically transmissive material.

2. The method of claim 1, further comprising, subsequent to said curing step, encapsulating the die, die pad, optically transmissive media, and window with an encapsulating material.

3. The method of claim 1, wherein said curing step comprises partially curing the optically transmissive material, the method further comprising, while said optically transmissive material is partially cured, the further step of encapsulating the die, die pad, optically transmissive media, and window with an encapsulating material.

4. The method of claim 1, wherein the pressing step comprises placing the die, die pad, optically transmissive media, and window into an encapsulation mold having surfaces therein that press the window into the deposit of optically transmissive material until a selected dimension between the window and a selected reference plane is attained.

5. The method of claim 4, wherein the curing is completed in the encapsulation mold.

6. A method of fabricating a semiconductor package having a die mounted on a die pad, the die having at least one optical component therein or thereon, comprising:
depositing a selected quantity of an uncured optically transmissive material on at least one side of an optically transmissive window;
placing the optically transmissive window and the optically transmissive material on that portion or those portions of the die having the at least one optical component therein or thereon;
pressing the window into the deposit of optically transmissive material until a selected dimension between the window and a selected reference plane is attained; and
curing the optically transmissive material.

7. The method of claim 6, further comprising, subsequent to said curing step, encapsulating the die, die pad, optically transmissive media, and window with an encapsulating material.

8. The method of claim 6, wherein said curing step comprises partially curing the optically transmissive material, the method further comprising, while said optically transmissive material is partially cured, the further step of encapsulating the die, die pad, optically transmissive media, and window with an encapsulating material.

9. The method of claim 6, wherein the pressing step comprises placing the die, die pad, optically transmissive media, and window into an encapsulation mold having surfaces therein that press the window into the deposit of optically transmissive material until a selected dimension between the window and a selected reference plane is attained.

10. The method of claim 9, wherein the curing is completed in the encapsulation mold.

11. A semiconductor device package having an optically transmissive window therein for coupling optical energy to and/or from at least one optical component within the package, comprising:
a semiconductor die mounted on a die pad and having at least one optical component formed thereon or therein and conductive pads thereon connected by wiring to leads;
optically transmissive media on the die at least in that area or those areas thereof having the at least one optical component formed thereon or therein;
an optically transmissve window coupled to the optically transmissive media; and.
a encapsulating material forming an encapsulation package, at least one surface of the window substantially free of the encapsulating material;
the optically transmissive media formed by depositing a selected quantity of an uncured optically transmissive material on at least that portion of the die having the optical components thereon or therein, placing the window on the deposit of optically transmissive media, pressing the window into the deposit of optically transmissive media until a selected dimension between the window and selected plane is attained, and curing the optically transmissive material.

12. A semiconductor device package having an optically transmissive window therein for coupling optical energy to and/or from at least one optical component within the package, comprising:
a semiconductor die mounted on a die pad and having at least one optical component formed thereon or therein and conductive pads thereon connected by wiring to leads;
optically transmissive media on the die at least in that area or those areas thereof having the at least one optical component formed thereon or therein;
an optically transmissve window coupled to the optically transmissive media; and
an encapsulating material forming an encapsulation package, at least one surface of the window substantially free of the encapsulating material;
the optically transmissive media formed by depositing a selected quantity of an uncured optically transmissive material on one side of the window, placing the window and its deposit of optically transmissive material on at least that portion or those portions of the die having the at least one optical component thereon or therein, pressing the window into the deposit of optically transmissive media until a selected dimension between the window and selected plane is attained, and curing the optically transmissive material.
